(19) United States
(12) Patent Application Publication
(10) Pub. No.: US 2019/0386066 A1
(43) Pub. Date: Dec. 19, 2019

(54) A FLEXIBLE OLED DISPLAY PANEL AND A MANUFACTURING METHOD THEREOF

(71) Applicant: Wuhan China Star Optoelectronics Semiconductor Display Technology Co., Ltd., Wuhan, Hubei (CN)

(72) Inventor: Mengqi CAI, Wuhan, Hubei (CN)

(21) Appl. No.: 15/579,229

(22) PCT Filed: Nov. 28, 2017
(86) PCT No.: PCT/CN2017/113223

§ 371 Date: Dec. 4, 2017

(30) Foreign Application Priority Data
Nov. 22, 2017 (CN) 201711171342.X

(51) Int. Cl. H01L 27/32; H01L 21/78

(52) U.S. Cl. CPC H01L 27/32; H01L 2251/566; H01L 2251/5338; H01L 21/7813

(57) ABSTRACT

The present disclosure provides a manufacturing method of a flexible OLED display panel, comprising: providing a supporting substrate, and forming a flexible OLED motherboard on a second surface of supporting substrate, the flexible OLED motherboard comprises a plurality of flexible OLED display panel arranged at intervals; providing a mask-plate on a first surface of supporting substrate opposite to second surface, light-transmitting units being disposed on the mask-plate corresponding to each of the flexible OLED display panels; irradiating the supporting substrate from the mask-plate by laser, forming a separation area in a connection interface of the flexible OLED motherboard and supporting substrate corresponding to the light-transmitting units, and the flexible OLED display panel being located in the separation area; cutting the flexible OLED motherboard by a laser cutting process along an internal edge of the separation area, peeling off a plurality of the flexible OLED display panels from the supporting substrate.

### RELATED APPLICATIONS

The present application is a National Phase of International Application Number PCT/CN2017/113223, filed Nov. 28, 2017, and claims the priority of China Application 201711171342.X, filed Nov. 22, 2017.

### FIELD OF THE DISCLOSURE

The disclosure relates to a display technical field, and more particularly to a flexible OLED display panel and a manufacturing method thereof.

### BACKGROUND

Organic Light-emitting Diodes (OLED) display panel has many advantages, such as self-luminous, high contrast, thin thickness, wide-viewing angle, fast response and so on, which is a representative of a new generation of a display panel technology, more and more respected by an industry. A flexible OLED display panel is one of an important trend, generally, a flexible OLED display panel comprises a flexible substrate and an OLED display unit formed on the flexible substrate, and the OLED display unit includes a thin-film transistor array layer, an anode layer, an organic light-emitting layer, a cathode layer and an encapsulation layer formed on the flexible substrate respectively.

The flexible OLED display panel can not only be thinner and lighter in size, but also reduce a power consumption, thereby helping to enhance a life of a corresponding product. Meanwhile, due to a bendable ability and a flexibility of the flexible OLED display panel, a durability of the OLED display panel is also higher than that of a conventional hard display panel. The flexible OLED display panel can be widely used in a variety of products with display capabilities, such as can be used in notebooks, televisions, mobile terminals and a variety of wearable devices.

The flexible OLED display panel brings a series of advantages as well as its own defects. Because the flexible substrate has problems of the flexibility and a thermal expansibility, it brings inconvenience to a processing of a display device, easily causes the substrate to sag and even causes to wrinkle or break. It is difficult to accurately follow a film preparation process. In order to solve problems, the flexible substrate needs to be connected to a rigid substrate such as a glass substrate for supporting and fixing the flexible substrate to facilitate a formation of a thin film. After each layer of elements forming the display panel are manufactured on the flexible substrate, the rigid substrate is peeled off from the flexible substrate through a peeling process to complete a manufacturing of the flexible display panel.

Currently, a manufacturing method of a mainstream flexible OLED display panel comprises the following steps:

First, using the glass substrate as a carrier, a polyimide (PI) film is coated on the entire glass substrate to cure the PI film, and the PI film serves as the flexible substrate.

Second, the thin-film transistor array layer, the anode layer, the organic light-emitting layer, the cathode layer and the encapsulation layer are sequentially fabricated from the PI film, so that a flexible OLED display motherboard is manufactured.

Third, applying a cutting process, the glass substrate and the flexible OLED display motherboard are split into pieces to form a single-piece flexible OLED display panel.

Fourth, for each single-piece flexible OLED display panel, a laser lift off (LLO) process is used to separate the PI film from the glass substrate to obtain a flexible OLED display panel.

In the processing steps above, for the cutting process in step three, a laser cutting equipment is usually used to accurately cut the flexible OLED display motherboard. As we all know, the laser cutting equipment is more expensive and a cost of equipment is also higher. In the step three above, the glass substrate is also cut during the laser cutting process, which not only consumes working time and material, but also increases a loss and a using cost of the laser cutting equipment.

Therefore, a prior art still needs to be improved and developed.

### SUMMARY

Due to the deficiencies of a prior art, the present disclosure provides a manufacturing method for a flexible OLED display panel to improve a generating efficiency and reduce a productive cost.

To achieve the purposes above, the present disclosure adopts the technical methods:

A manufacturing method of a flexible OLED display panel, comprising:

Providing a supporting substrate, and forming a flexible OLED motherboard on a second surface of the supporting substrate, the flexible OLED motherboard comprises comprising a plurality of flexible OLED display panel arranged at intervals;

Providing a mask-plate on a first surface of the supporting substrate opposite to the second surface, light-transmitting units being disposed on the mask-plate corresponding to each of the flexible OLED display panel;

Irradiating the supporting substrate from the mask-plate by laser, forming a separation area in a connection interface of the flexible OLED motherboard and the supporting substrate corresponding to the light-transmitting unit, and the flexible OLED display panel being located in the separation area; and

Cutting the flexible OLED motherboard by a laser cutting process along an internal edge of the separation area, and peeling off the plurality of the flexible OLED display panels from the supporting substrate.

Wherein in the step of forming the flexible OLED motherboard on the second surface of the supporting substrate specifically comprises:

Applying a coating process, and forming a flexible substrate on the second surface of the supporting substrate; and

Preparing a plurality of OLED display units arranged at intervals on the flexible substrate,

Wherein a material of the flexible substrate is a polyimide, a polycarbonate, a polyethersulfone, a polyethylene terephthalate, a polyethylene naphthalate, a polyarylate, or a glass-fiber reinforced plastic.

Wherein the OLED display unit comprises a thin-film transistor array layer, an anode layer, an organic light-emitting layer, and a cathode layer formed on the flexible substrate sequentially.

Wherein the plurality of the flexible OLED display panels are the same size and are arranged in a regular array on the flexible OLED motherboard, and the light-transmitting units on the mask-plate corresponds to the plurality of the flexible OLED display panels one by one, and a projection of the light-transmitting unit on the flexible OLED motherboard completely covers the corresponding flexible OLED display panel.

Wherein the plurality of the flexible OLED display panels comprises a variety of standard sizes of the flexible OLED display panel, and the light-transmitting units on the mask-plate corresponds to the plurality of the flexible OLED display panels one by one, and a projection of the light-transmitting unit on the flexible OLED motherboard completely covers the corresponding flexible OLED display panel.

Wherein, setting the plurality of criss-cross cutting lines on the flexible OLED motherboard, and arranging a cutting line between an internal edge of the separation area and an external edge of the flexible OLED display panel, and using a laser cutting process along the cutting line, and cutting the flexible OLED motherboard, and peeling off the plurality of the flexible OLED display panel from the supporting substrate.

Wherein a distance between the external edge of the flexible OLED display panel and the internal edge of the separation area is 1˜2 mm and a distance between the cutting line and the internal edge of the separation area is 0˜1 mm.

Wherein the distance between the cutting line and the internal edge of the separation area is 0.5˜1 mm.

Wherein the supporting substrate is a glass substrate, and the mask-plate is an aluminum-alloy mask-plate.

The embodiment of the present disclosure provides the manufacturing method of the flexible OLED display panel, firstly, setting the mask-plate on the back of the supporting substrate and applying the laser lift off (LLO) process, and the connection interface between the flexible OLED motherboard and the supporting substrate forms the separation area corresponding to each flexible OLED display panel; then along the medial border of the separation area and the flexible OLED motherboard cut by applying the laser cutting process, peeling more of the flexible OLED display panel from the supporting substrate. The manufacturing method does not need to cut the pieces for the supporting substrate, which not only avoids consuming more working time and material, but also reduces the loss of the laser cutting equipment and the using cost, thereby, the productive efficiency of the flexible OLED display panel is improved, and the productive cost is reduced.

### BRIEF DESCRIPTION OF THE DRAWINGS

FIG. 1 is a processing flow chart of a manufacturing method of a flexible OLED display panel according to an embodiment of the present disclosure;

FIGS. 2a to 2g are acquired exemplary diagrams of device structures corresponding to each step in a manufacturing method of a flexible OLED display panel according to an embodiment of the present disclosure.

### DETAILED DESCRIPTION OF PREFERRED EMBODIMENTS

To make the objectives, the technical solutions, and the advantages of the present disclosure clearer, the following describes a specific embodiment method of the present disclosure in detail with reference to the accompanying figures. Examples of these preferred embodiments are illustrated in the figures. The embodiments of the present disclosure shown in the figures and described in the figures are merely exemplary and the present disclosure is not limited to these embodiments.

Here, it should also be illustrated that in order to avoid obscuring the present disclosure by unnecessary details, the accompanying figures only shows the structures and/or the processing steps that are closely related to the solutions according to the present disclosure, and omitting other details which is not relevant to the present disclosure.

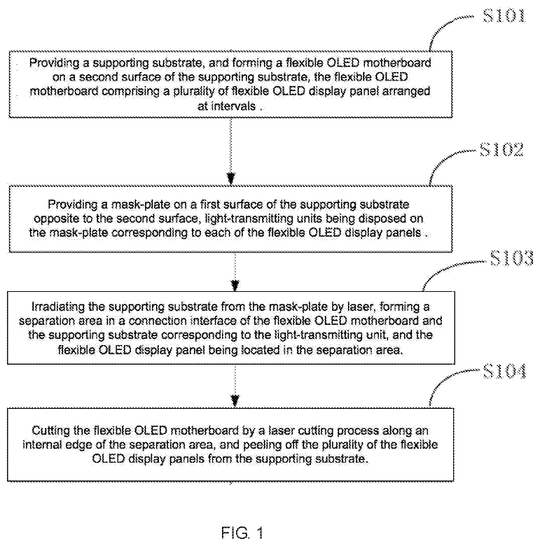

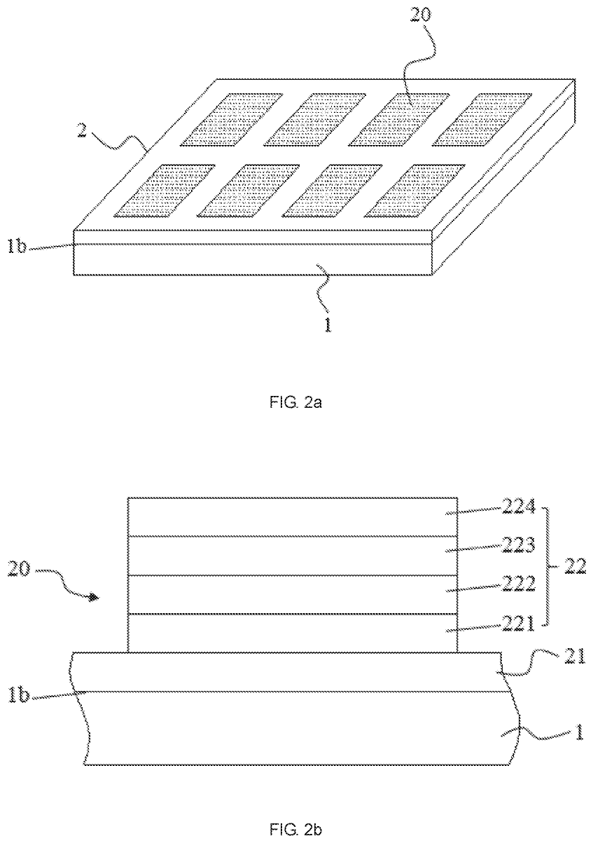

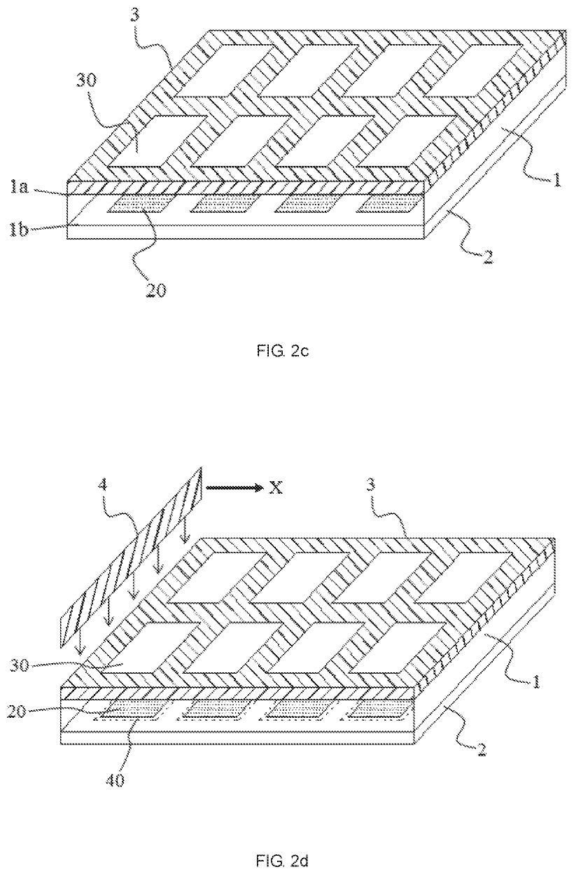

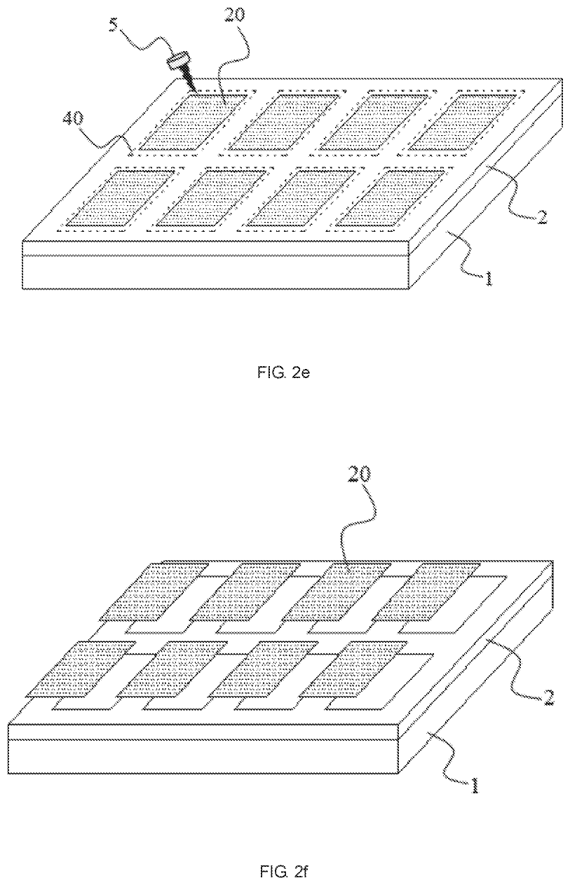

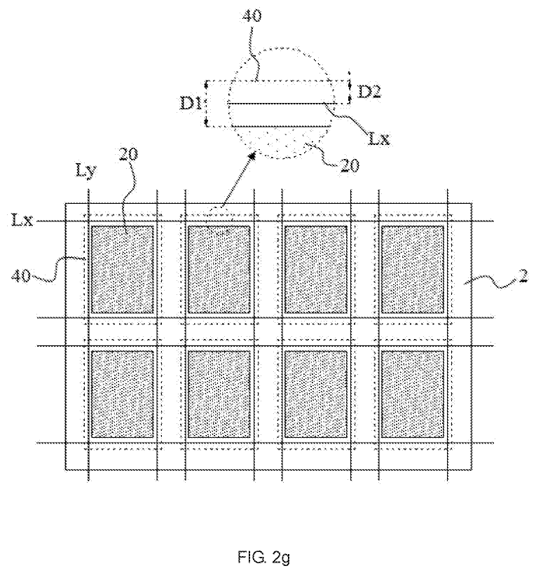

See FIG. 1 and FIG. 2a-2d specifically, an embodiment provides a manufacturing method of a flexible OLED display panel, and the manufacturing method comprises the following steps:

S101, see FIG. 2a and FIG. 2b, forming a flexible OLED motherboard 2 on a second surface 1b of the supporting substrate 1, wherein the flexible OLED motherboard 2 comprises a plurality of flexible OLED display panel 20 arranged at intervals. The step comprises specifically: applying the coating process to form a flexible substrate 21 on the second surface 1b of the supporting substrate 1 firstly, and then forming the plurality of OLED display units 22 on the flexible substrate; therefore, acquiring the flexible OLED motherboard 2 of the plurality of flexible OLED display panel 20 arranged at intervals.

Wherein FIG. 2b exemplarily shows a cross-sectional view of one of the flexible OLED display panel 20, which comprises the flexible substrate 21 and an OLED display unit 22 formed on the flexible substrate 21, and the OLED display unit 22, comprises a thin-film transistor array layer 221, an anode layer 222, an organic light-emitting layer 223, a cathode layer 224 and so on, sequentially formed on the flexible substrate 21. Wherein a thin-film transistor, a data line and a scan line and each structural film layer set in the thin-film transistor array layer 221. Wherein the organic light-emitting layer 223 comprises a hole transport layer (HTL), an emissive layer (EML) and an electron transport layer (ETL) formed by an organic material. The specific manufacturing method of each functional film layer of the OLED display unit 20 can be selected according to any one of the processing technologies known in the art.

Wherein the supporting substrate is a glass substrate and the material of the flexible substrate is a polyimide, a polycarbonate, a polyethersulfone, a polyethylene terephthalate, a polyethylene naphthalate, a polyarylate, or a glass-fiber reinforced plastic.

In the embodiment, as shown in FIG. 2a, the plurality of flexible OLED display panel 20 are the same size and are arranged in a regular array on the flexible OLED motherboard 2, so that a processing difficulty can be reduced. In other some embodiments, the plurality of the flexible OLED display panel 20 also comprises a variety of standard size of the flexible OLED display panel 20, therefore, the flexible OLED display panel 20 with various sizes can be manufactured at the same time,

S102, see FIG. 2c, providing a mask-plate 3 on a first surface la of the supporting substrate 1 opposite to the second surface 1b, wherein light-transmitting units 30 being disposed on the mask-plate 3 corresponding to each of the flexible OLED display panels 20. Specifically, and the light-transmitting unit 30 on the mask-plate 3 corresponds to the plurality of the flexible OLED display panel 20 one by one, and a projection of the light-transmitting unit on the flexible OLED motherboard 2 completely covers the corresponding flexible OLED display panel 20. It should be illustrated that, in order to clearly show a correspondence between the light-transmitting unit 30 and the flexible OLED display panel 20, and a part of the flexible OLED display panel 20 is shown in a perspective view in FIG. 2c.

Wherein the mask-plate 3 can be chosen as an aluminum-alloy mask-plate. A specific structure of the mask-plate 3 need to be designed specifically according to a size and an arrangement of the flexible OLED display panel 20 on the flexible OLED motherboard 2.

S103, see FIG. 2d, adopting a laser 4 to irradiate from the mask-plate 3 to the supporting substrate 1 (as shown in FIG. 2d continuous scanning along a X-direction irradiation), wherein a separation area 40 is formed in a connection interface of the flexible OLED motherboard 2 and the supporting substrate 1 corresponding to the light-transmitting unit 30, and the flexible OLED display panel 20 is located in the separation area 40. Specifically, the step is to separate the supporting substrate 1 and the flexible substrate 21 in the region irradiated with the laser by a laser lift-off process (LLO), that is to say, in the separation region 40, the supporting substrate 1 and the flexible substrate 21 is separated from each other.

Wherein the size of the separation area 40 is the same as the size of the light-transmitting unit 30; therefore, the size and the arrangement of the light-transmitting unit 30 in the mask-plate 3 are specifically designed according to the size and the arrangement of the flexible OLED display panel 20, and then, a distance between the external edge of the flexible OLED display panel 20 and the internal edge of the separation area 40 can be controlled.

S104, see FIG. 2e and FIG. 2f, cutting the flexible OLED motherboard 2 by a laser cutting process 5 along an internal edge of the separation area 40, and peeling off a plurality of the flexible OLED display panel 20 from the supporting substrate 1.

Specifically, in the embodiment, see FIG. 2g, firstly, the plurality of criss-cross cutting lines Lx, Ly are arranged on the flexible OLED motherboard 2, and the cutting lines Lx, Ly are arranged on the internal edge of the separating area 40 and the external edge of the flexible OLED display panel 20, and then, the flexible OLED motherboard 2 is cut along the cutting lines Lx, Ly using the laser cutting process, thereby peeling off the plurality of flexible OLED display panels 20 from the supporting substrate 1.

In a preferred embodiment, as shown in FIG. 2g, the distance D1 between the external edge of the flexible OLED display panel 20 and the internal edge of the separation region 40 is set within a range of 1-2 mm, and a distance D2 between the cutting lines Lx, Ly and the internal edge of the separation region 40 is set within a range of 0-1 mm.

According to the manufacturing method of the flexible OLED display panel provided in the above embodiment, firstly, setting the mask-plate on the back of the supporting substrate and applying the laser lift off (LLO) process, and the connection interface between the flexible OLED motherboard and the supporting substrate forms the separation area corresponding to each flexible OLED display panel; then along the internal border of the separation area and the flexible OLED motherboard cut by applying the laser cutting process, peeling more of the flexible OLED display panel from the supporting substrate. Compared with the prior art, the manufacturing method does not need to cut the pieces for the supporting substrate (glass substrate), which has the following advantages:

First, as the flexible OLED motherboard is cut by using a laser cutting device, the supporting substrate does not need to be cut, which avoids consuming more working time and material, and reduces the loss and the using cost of the laser cutting device.

Second, by disposing the mask-plate, using a one-time laser lift-off process for the plurality of flexible OLED display panel to peel off simultaneously, compared with the prior art, splitting the pieces and then separately performing the laser lift-off process, the working efficiency of the laser lift-off process is improved and saves production working time.

Third, because it is not necessary to cut the supporting substrate, the supporting substrate can be reused and reduce the production cost.

In summary, the manufacturing method of a flexible OLED display panel provided by the embodiment of the present disclosure can improve the production efficiency of the flexible OLED display panel and reduce the production cost.

It should be illustrated that, in this document, relational terms such as first and second are merely used to distinguish one entity or operation from another entity or operation, and do not necessarily require or imply any actual relationship or order between such entities or operations. Moreover, the terms “comprise”, “comprise” or any other variations thereof are intended to cover a non-exclusive comprising, so that comprises a series of elements of a process, a method, an article or device includes not only those elements, and comprises not only those elements, but also other elements not specifically listed, or elements inherent to the process, the method, the article, or the device. Without further limitations, the element limited by the statement “comprising a . . . ” does not exclude the existence of additional identical elements in the process, the method, the article, or the device that comprises the element.

The above descriptions are merely specific implementation methods of the present application. It should be noted that those skilled in the art may make various improvements and modifications without departing from the principle of the present application, and these improvements and modifications should also be considered as falling within the protection scope of the present application.

What is claimed is:

1. A manufacturing method of a flexible OLED display panel, comprising:
providing a supporting substrate, and forming a flexible OLED motherboard on a second surface of the supporting substrate, the flexible OLED motherboard comprising a plurality of flexible OLED display panel arranged at intervals;
providing a mask-plate on a first surface of the supporting substrate opposite to the second surface, light-transmitting units being disposed on the mask-plate corresponding to each of the flexible OLED display panels;
irradiating the supporting substrate from the mask-plate by laser, forming a separation area in a connection interface of the flexible OLED motherboard and the supporting substrate corresponding to the light-transmitting unit, and the flexible OLED display panel being located in the separation area; and
cutting the flexible OLED motherboard by a laser cutting process along an internal edge of the separation area, and peeling off the plurality of the flexible OLED display panels from the supporting substrate.

2. The manufacturing method of a flexible OLED display panel according to claim 1, wherein in the step of forming the flexible OLED motherboard on the second surface of the supporting substrate specifically comprises:
applying a coating process, and forming a flexible substrate on the second surface of the supporting substrate; and
preparing a plurality of OLED display units arranged at intervals on the flexible substrate.

3. The manufacturing method of a flexible OLED display panel according to claim 2, wherein a material of the flexible substrate is a polyimide, a polycarbonate, a polyethersulfone, a polyethylene terephthalate, a polyethylene naphthalate, a polyarylate, or a glass-fiber reinforced plastic.

4. The manufacturing method of a flexible OLED display panel according to claim 2, wherein the OLED display unit comprises a thin-film transistor array layer, an anode layer, an organic light-emitting layer, and a cathode layer formed on the flexible substrate sequentially.

5. The manufacturing method of a flexible OLED display panel according to claim 1, wherein the plurality of the flexible OLED display panels are the same size and are arranged in a regular array on the flexible OLED motherboard, and the light-transmitting units on the mask-plate corresponds to the plurality of the flexible OLED display panels one by one, and a projection of the light-transmitting unit on the flexible OLED motherboard completely covers the corresponding flexible OLED display panel.

6. The manufacturing method of a flexible OLED display panel according to claim 1, wherein the plurality of the flexible OLED display panels comprises a variety of standard sizes of the flexible OLED display panel, and the light-transmitting units on the mask-plate corresponds to the plurality of the flexible OLED display panels one by one, and a projection of the light-transmitting unit on the flexible OLED motherboard completely covers the corresponding flexible OLED display panel.

7. The manufacturing method of a flexible OLED display panel according to claim 1, wherein the supporting substrate is a glass substrate.

8. The manufacturing method of a flexible OLED display panel according to claim 1, wherein the mask-plate is an aluminum-alloy mask-plate.

9. A manufacturing method of a flexible OLED display panel, comprising:
providing a supporting substrate, and forming a flexible OLED motherboard on a second surface of the supporting substrate, the flexible OLED motherboard comprising a plurality of flexible OLED display panel arranged at intervals;
providing a mask-plate on a first surface of the supporting substrate opposite to the second surface, light-transmitting units being disposed on the mask-plate corresponding to each of the flexible OLED display panels;
irradiating the supporting substrate from the mask-plate by laser, forming a separation area in a connection interface of the flexible OLED motherboard and the supporting substrate corresponding to the light-transmitting unit, and the flexible OLED display panel being located in the separation area; and
setting the plurality of criss-cross cutting lines on the flexible OLED motherboard, and arranging a cutting line between an internal edge of the separation area and an external edge of the flexible OLED display panel;
using a laser cutting process along the cutting line, and cutting the flexible OLED motherboard, and peeling off the plurality of the flexible OLED display panel from the supporting substrate.

10. The manufacturing method of a flexible OLED display panel according to claim 9, wherein a distance between the external edge of the flexible OLED display panel and the internal edge of the separation area is 1˜2 mm, and a distance between the cutting line and the internal edge of the separation area is 0˜1 mm.

11. The manufacturing method of a flexible OLED display panel according to claim 10, wherein the distance between the cutting line and the internal edge of the separation area is 0.5˜1 mm.

12. The manufacturing method of a flexible OLED display panel according to claim 9, wherein in the step of forming the flexible OLED motherboard on the second surface of the supporting substrate specifically comprises:
applying a coating process, and forming a flexible substrate on the second surface of the supporting substrate; and
preparing a plurality of OLED display units arranged at intervals on the flexible substrate.

13. The manufacturing method of a flexible OLED display panel according to claim 12, wherein a material of the flexible substrate is a polyimide, a polycarbonate, a polyethersulfone, a polyethylene terephthalate, a polyethylene naphthalate, a polyarylate, or a glass-fiber reinforced plastic.

14. The manufacturing method of a flexible OLED display panel according to claim 12, wherein the OLED display unit comprises a thin film transistor array layer, an anode layer, an organic light-emitting layer, and a cathode layer formed on the flexible substrate sequentially.

15. The manufacturing method of a flexible OLED display panel according to claim 9, wherein the plurality of the flexible OLED display panels are the same size and are arranged in a regular array on the flexible OLED motherboard, and the light-transmitting unit on the mask-plate corresponds to the plurality of the flexible OLED display panels one by one, and a projection of the light-transmitting unit on the flexible OLED motherboard completely covers the corresponding flexible OLED display panel.

16. The manufacturing method of a flexible OLED display panel according to claim 9, wherein the plurality of the flexible OLED display panels comprises a variety of standard size of the flexible OLED display panel, and the light-transmitting unit on the mask-plate corresponds to the plurality of the flexible OLED display panels one by one, and the projection of the light-transmitting unit on the flexible OLED motherboard completely covers the corresponding flexible OLED display panel.

17. The manufacturing method of a flexible OLED display panel according to claim 9, wherein the supporting substrate is a glass substrate.

18. The manufacturing method of a flexible OLED display panel according to claim 9, wherein the mask-plate is an aluminum-alloy mask-plate.
